(19) United States
(12) Patent Application Publication
(10) Pub. No.: US 2012/0081187 A1
(43) Pub. Date: Apr. 5, 2012

(54) Oscillator

(75) Inventor: Mitsuaki Koyama, Sayama-shi (JP)

(73) Assignee: NIHON DEMPA KOGYO CO., LTD., Shibuya-ku (JP)

(21) Appl. No.: 13/200,612

(22) Filed: Sep. 27, 2011

(30) Foreign Application Priority Data
Sep. 30, 2010 (JP) 2010-222874

(51) Int. Cl. H03K 3/36

(52) U.S. Cl. 331/116 FE

(57) ABSTRACT

An oscillator outputs a sine wave with high purity capable of reducing phase noise. In a Colpitts oscillator circuit using a transistor as an amplifying part, a quartz-crystal resonator for waveform shaping is provided outside or inside an oscillation loop. A quartz-crystal resonator for oscillation and the quartz-crystal resonator for waveform shaping are formed, with an electrode pair and an electrode pair being provided on a common quartz-crystal piece. A separation distance between the electrode of the quartz-crystal resonator and the electrode of the quartz-crystal resonator is set large so that they are not elastically coupled, or even when they are elastically coupled, their coupling degree is weak, and an inductor causing parallel resonance with a parallel capacitance of the quartz-crystal resonator is provided.

### BACKGROUND OF THE INVENTION

1. Field of the Invention

The present invention relates to an oscillator.

2. Description of the Related Art

A quartz-crystal oscillator oscillates by connecting an amplifier to a resonant circuit including a quartz-crystal resonator, and a voltage waveform corresponding to an oscillation waveform of the quartz-crystal resonator is a sine wave. However, the waveform of the sine wave output from the quartz-crystal resonator is distorted when the sine wave passes through a circuit part such as the amplifier.

A demand for frequency stabilization of a signal represented by a signal of GPS is increasing year by year, and recent years have seen not a small demand that what is called a floor level at a 10 kHz detuning frequency or higher should be −160 dBc or lower in terms of SSB phase noise. Further, in an area where the detuning frequency is 1 kHz or lower, noise reduction is also required, and to realize this has been an issue to be attained. Whether the phase noise is large or small influences purity of a signal and it is necessary to increase the purity of the signal more than ever, which requires a measure for preventing the aforesaid distortion of the waveform of the sine wave. Here, based on an idea to prevent the passage of a signal in an electronic circuit as much as possible, there has been considered a technique to provide a quartz-crystal resonant circuit outside an oscillator to reduce phase noise by negative feedback. However, the circuit in this method has a complicated structure and is difficult to manufacture at low cost, which makes it difficult to produce it on a commercial basis.

Patent Document 1 describes a structure in which two pairs of electrodes are provided on a common quartz-crystal resonator and are elastically coupled to each other, and one of the pairs is used as a quartz-crystal resonator part for oscillation and the other pair is connected to a variable capacitance element. This technique, however, is to compensate a frequency-temperature characteristic and is not a technique relating to waveform shaping.

Further, Patent Document 2 describes a structure in which an oscillator circuit including a quartz-crystal resonator outputs a rectangular wave, and a quartz-crystal resonator for shaping the rectangular wave to a sine wave is provided on an output side of the oscillator circuit. However, the latter quartz-crystal resonator is not for shaping the sine wave and does not sufficiently remove a noise component included in a frequency signal.

[Patent Document 1] Japanese Patent Application Laid-open No. Hei 3-252213: FIG. 6, middle paragraph of the upper left column on page 2

[Patent Document 2] Japanese Patent Application Laid-open No. 2007-108170: FIG. 13

### SUMMARY OF THE INVENTION

The present invention was made under the above circumstances, and has an object to provide an oscillator capable of reducing phase noise.

An invention according to an aspect of the present invention is an oscillator which includes an oscillating part including a quartz-crystal resonator for oscillation; and an amplifying part amplifying a frequency signal oscillated by the oscillating part to feed the frequency signal back to the oscillating part, the oscillator including:

a quartz-crystal resonator for waveform shaping provided inside or outside an oscillation loop including the oscillating part and the amplifying part to shape the frequency signal to a sine wave; and

an inductor connected in parallel to the quartz-crystal resonator for waveform shaping and causing parallel resonance at an intended output frequency with a parallel capacitance exhibited in an equivalent circuit of the quartz-crystal resonator for waveform shaping,

wherein the quartz-crystal resonator for oscillation and the quartz-crystal resonator for waveform shaping use a common quartz-crystal piece, with a pair of electrodes forming an oscillation area of the quartz-crystal resonator for oscillation being provided on both surfaces of the quartz-crystal piece respectively, and with a pair of electrodes forming an oscillation area of the quartz-crystal resonator for waveform shaping being provided on the both surfaces of the quartz-crystal piece respectively, and

wherein the electrodes of the quartz-crystal resonator for oscillation and the electrodes of the quartz-crystal resonator for waveform shaping are not elastically coupled to each other or have weak elastic coupling.

An invention according to another aspect is an oscillator which includes: an oscillating part including an elastic wave resonator for oscillation; and an amplifying part amplifying a frequency signal oscillated by the oscillating part to feed the frequency signal back to the oscillating part, the oscillator including

an elastic wave resonator for waveform shaping provided inside or outside an oscillation loop including the oscillating part and the amplifying part to shape the frequency signal to a sine wave,

wherein IDT electrodes of the elastic wave resonator for oscillation and the elastic wave resonator for waveform shaping are disposed on a common piezoelectric piece.

According to the present invention, since, in the oscillator including the oscillating part including the quartz-crystal resonator, the quartz-crystal resonator for waveform shaping to shape the frequency signal to the sine wave is provided inside or outside the oscillation loop, the distortion of the waveform is reduced, which enables a reduction in phase noise. The electrodes of the quartz-crystal resonator for oscillation and the electrodes of the quartz-crystal resonator for waveform shaping are provided on the common quartz-crystal piece and the quartz-crystal resonators are both placed in the same environment, and hence when the temperature changes, oscillation frequencies of the both quartz-crystal resonators change to the same degree. Therefore, even if the temperature changes, an effect of reducing phase noise is not impaired. Further, since the inductor causing the parallel resonance at the intended output frequency with the parallel capacitance of the quartz-crystal resonator for waveform shaping is provided, the frequency signal mainly passes through a mechanically oscillating portion in the quartz-crystal resonator, so that a noise component included in the intended frequency signal, for example, a fundamental wave, is removed. Therefore, the phase noise can be further reduced.

According to the other aspect of the invention, since, in the oscillator including the oscillating part including the elastic wave resonator, the elastic wave resonator for waveform shaping to shape the frequency signal to the sine wave is provided inside or outside the oscillation loop, the distortion of the waveform is reduced, which makes it possible to reduce phase noise.

The electrodes of the elastic wave resonator for oscillation and the elastic wave resonator for waveform shaping are provided on the common piezoelectric piece and the both elastic wave resonators are placed in the same environment, and therefore, the effect of reducing the phase noise is not impaired as described above.

### BRIEF DESCRIPTION OF THE DRAWINGS

FIG. 1 is a circuit diagram showing a first embodiment of the present invention;

FIG. 2(a) is a vertical sectional view showing quartz-crystal resonators used in the first embodiment and FIG. 2(b) is a plane view thereof;

FIG. 3 is a circuit diagram showing an equivalent circuit of the quartz-crystal resonator and an inductance;

FIG. 4(a) and FIG. 4(b) are conceptual charts of a frequency response when purity of a sine wave in an oscillation output is low and when the purity thereof is high, respectively;

FIG. 5 is a circuit diagram showing another example of the first embodiment;

FIG. 6 is a circuit diagram showing still another example of the first embodiment;

FIG. 7 is an explanatory chart showing experiment results;

FIG. 8 is a block diagram showing an example of elastic wave resonators used in a second embodiment of the present invention;

FIG. 9 is a block diagram showing another example of the elastic wave resonators used in the second embodiment of the present invention;

FIG. 10(a) and FIG. 10(b) are circuit diagrams showing modification examples of the present invention; and

FIG. 11(a) to FIG. 11(c) are circuit diagrams showing modification examples of the present invention.

### DETAILED DESCRIPTION OF THE PREFERRED EMBODIMENTS

### First Embodiment

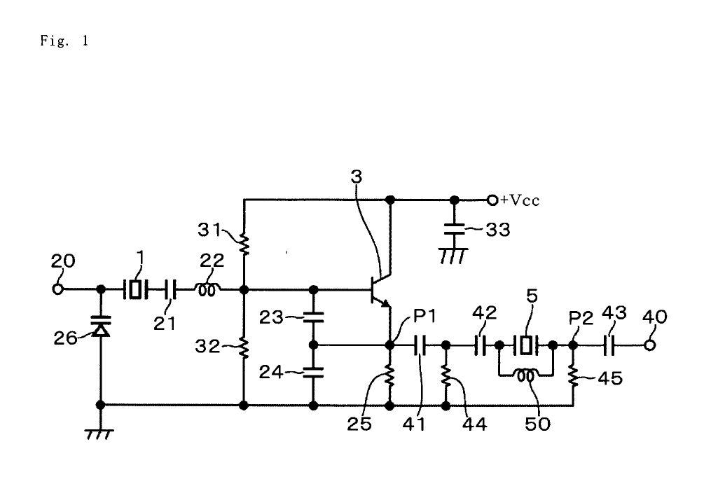

FIG. 1 is a circuit diagram showing a first embodiment of an oscillator of the present invention. The circuit in FIG. 1 is configured as a Colpitts oscillator circuit, and 1 denotes a quartz-crystal resonator for oscillation. One end of the quartz-crystal resonator 1 is connected to a base of a NPN transistor 3, which is an amplifying part, via a capacitor 21 for frequency adjustment and an extension coil 22. The transistor 3 amplifies a frequency signal oscillated by the quartz-crystal resonator 1 to feed the resultant frequency signal back to the quartz-crystal resonator 1. Between the base of the transistor 3 and a ground, a series circuit of capacitors 23, 24 for voltage division is provided, and a midpoint of the capacitors 23, 24 is connected to an emitter of the transistor 3.

Further, a DC power supply part Vcc applies a DC voltage of +Vcc to a series circuit of bleeder resistors 31, 32, and the voltage at a midpoint of the bleeder resistors 31, 32 is supplied to the base of the transistor 3. 33 denotes a capacitor and 25 denotes a feedback resistor. A variable capacitance element 26 whose capacitance varies by voltage application is connected to the other end of the quartz-crystal resonator 1 for oscillation. The supply of control voltage to a control voltage terminal 20 causes the change in the capacitance of the variable capacitance element 26 to adjust an oscillation frequency. The quartz-crystal resonator 1, the capacitor 21, the extension coil 22, and the variable capacitor element 26 are constituent elements of an oscillating part.

On the emitter side of the transistor 3, a circuit for taking out an output frequency signal is provided outside an oscillation loop, and this circuit includes a series circuit of capacitors 41, 42, a quartz-crystal resonator 5 for waveform shaping, and a capacitor 43. 40 denotes an output terminal. Further, one-side ends of resistors 44, 45 are connected to both ends of a series circuit of the capacitor 42 and the quartz-crystal resonator 5 respectively, and the other ends of these resistors 44, 45 are grounded. The capacitor 41 is for DC cut, and the capacitors 42, 43 and the resistors 44, 45 form filters for attenuating a frequency signal with a frequency other than an intended frequency.

The quartz-crystal resonator 5 for waveform shaping is intended to shape the frequency signal taken out from the oscillation loop to a sine wave with high purity (sine wave with reduced distortion).

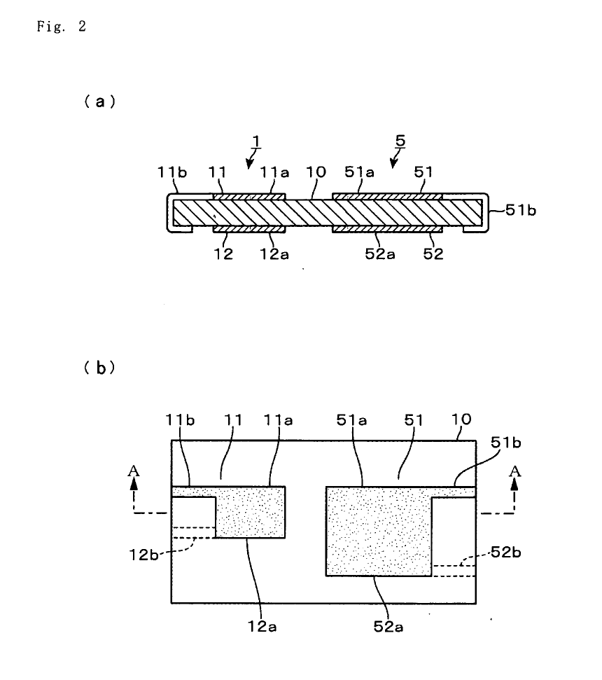

The quartz-crystal resonator 1 for oscillation and the quartz-crystal resonator 5 for waveform shaping use, for example, an AT-cut quartz-crystal piece 10 in a strip shape as a common quartz-crystal piece as shown in FIG. 2(a). This quartz-crystal piece 10 includes a pair of first electrodes 11, 12 provided on its front and rear surfaces respectively and a pair of second electrodes 51, 52 provided on its front and rear surfaces respectively. The first electrodes 11, 12 and the second electrodes 51, 52 are provided on a left portion and a right portion of the quartz-crystal piece 10 to be apart from each other and are set equal in thickness.

The first electrodes 11, 12 each include a rectangular excitation electrode 11a (12a) and a lead electrode 11b (12b) led out from the excitation electrode 11a (12a). The lead electrode 11b on the front surface of the quartz-crystal piece 10 is led to the rear surface, so that the lead electrodes 11b, 12b are arranged side by side at different positions two-dimensionally on the rear surface. The lead electrodes 11b, 12b correspond to both terminal parts of the quartz-crystal resonator 1 for oscillation respectively.

Further, the second electrodes 51, 52 each include a rectangular excitation electrode 51a (52a) and a lead electrode 51b (52b) led out from the excitation electrode 51a (52a). The lead electrode 51b on the front surface of the quartz-crystal piece 10 is led to the rear surface, so that the lead electrodes 51b, 52b are arranged side by side at different positions two-dimensionally on the rear surface. The lead electrodes 51b, 52b correspond to both terminal parts of the quartz-crystal resonator 5 for waveform shaping respectively.

An area where the excitation electrode 11a is provided corresponds to an oscillation area of the quartz-crystal resonator 1 for oscillation, and an area where the excitation electrode 51a is provided corresponds to an oscillation area of the quartz-crystal resonator 5 for waveform shaping. The first electrode 11 (12) and the second electrode 51 (52) are not elastically coupled, or even if they are elastically coupled, this is weak coupling. The “weak elastic coupling” mentioned in the description and the claims of the present application means as defined in the following. One of the electrode pairs (one of the pair of the first electrodes 11, 12 and the pair of the second electrodes 51, 52) is short-circuited, an oscillation frequency is measured in the other electrode pair, and the measured frequency is represented by f1. Next, one of the electrode pairs is set open, an oscillation frequency is measured in the other electrode pair, and the measured frequency is represented by f2. A case where a frequency deviation between f1 and f2 is 10 ppm or lower is defined as the “weak elastic coupling”. A case where there is no change between frequencies f1 and f2 is a state where they are not elastically coupled. Therefore, in other words, that the frequency deviation between f1 and f2 is 10 ppm or lower is a requirement in the present invention. When the first electrode 11 (12) and the second electrode 51 (52) are set in this manner, an influence, if any, that the oscillation of an active circuit has on a resonant circuit is extremely small, and therefore, these electrodes can be regarded as independent resonators.

As for the quartz-crystal resonator 1 for oscillation, in order to enhance frequency stability by reducing a series capacitance C1, the smaller the area of the electrode 11 (12), the more preferable. On the other hand, as for the quartz-crystal resonator 5 for waveform shaping, in order to facilitate the passage of the frequency signal, the larger the area of the electrode 51 (52), the more preferable. Therefore, it can be said that the area of the electrode 51 (52) is preferably larger than the area of the electrode 11 (12).

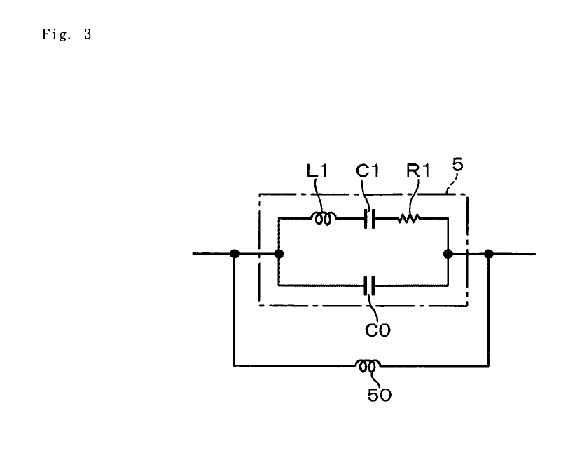

Further, an inductor 50 is provided in parallel to the quartz-crystal resonator 5 for waveform shaping. FIG. 3 shows an equivalent circuit of the quartz-crystal resonator 5 for waveform shaping, where L1 is an equivalent series inductance, C1 is an equivalent series capacitance, R1 is an equivalent series resistance, and C0 is a parallel capacitance. The inductor 50 is set to a value causing parallel resonance with the parallel capacitance C0 at an intended oscillation frequency f. That is, L, which is an inductance value of the inductor 50, is set so that the following expression holds.

f=1/{2π•√(L•C0}

Note that the parallel resonance can be caused by C0 and L because the equivalent series capacitance C1 is considerably smaller than the parallel capacitance C0.

In the embodiment described above, the quartz-crystal resonator 1 for oscillation oscillates at a frequency according to the voltage applied to the control terminal 20 and the frequency signal with the sine wave is generated. This frequency signal is fed back to the quartz-crystal resonator 1 via the transistor 3. At this time, the sine wave at a point P1 in FIG. 1 suffers distortion due to the transistor 3. The quartz-crystal resonator outputs the sine wave when excited, and therefore, when the distorted sine wave passes through the quartz-crystal resonator 5 for waveform shaping provided outside the oscillation loop, the distortion is removed therefrom, so that the waveform of the frequency signal at a point P2 becomes a sine wave with high purity.

Since the parallel capacitance C0 of the quartz-crystal resonator 5 for waveform shaping causes the parallel resonance with the inductor 50, the passage of a signal with the intended frequency (f) through the parallel capacitance C0 side is blocked. Accordingly, this frequency signal mainly passes through the mechanically oscillating portion, and thus the passage of noise included in this frequency signal is blocked.

Further, since the quartz-crystal resonator 1 for oscillation and the quartz-crystal resonator 5 for waveform shaping are provided on the common quartz-crystal piece 10, it can be said that the quartz-crystal resonators 1, 5 are both placed in the same temperature environment. Therefore, even when the temperature under which the quartz-crystal oscillator is placed changes, the frequencies of the both quartz-crystal resonators 1, 5 change to the same degree in accordance with the temperature change (their temperature change patterns are the same), and therefore, the effect of reducing the phase noise is not impaired.

On the other hand, when the quartz-crystal resonator 1 for oscillation and the quartz-crystal resonator 5 for waveform shaping are formed on different quartz-crystal pieces, their temperatures are often different. Therefore, change amounts from a reference temperature when the frequency is set by a manufacturer are different between the both quartz-crystal resonators 1, 5, and even when a control voltage corresponding to a frequency amount by which the frequency of the quartz-crystal resonator 1 for oscillation is to be changed is corrected, this correction amount differs from a frequency amount by which the frequency of the quartz-crystal resonator 5 for waveform shaping is to be changed. Therefore, the frequency taken out from the oscillation loop changes when the frequency signal passes through the quartz-crystal resonator 5 for waveform shaping.

According to the above-described embodiment, the quartz-crystal resonator 5 for waveform shaping to shape the frequency signal to the sine wave is provided outside the oscillation loop, and the inductor 50 blocks the passage of the frequency signal through the parallel capacitor C0 side of the quartz-crystal resonator 5. Therefore, the distortion of the waveform is reduced, which makes it possible to obtain the sine wave with high purity. Further, since the first electrodes 11, 12 and the second electrodes 51, 52 are not elastically coupled to each other or have weak elastic coupling, the oscillation area of the quartz-crystal resonator 1 for oscillation and the oscillation area of the quartz-crystal resonator 5 for waveform shaping can be regarded as independent resonators as previously described. Because of the above reasons, the phase noise can be reduced. Further, since the quartz-crystal resonator 1 for oscillation and the quartz-crystal resonator 5 for waveform shaping use the common quartz-crystal piece, the oscillation frequencies of the both quartz-crystal resonators change to the same degree when the temperature changes. Therefore, since the waveform shaping function is maintained, the effect of reducing the phase noise is not impaired even if the temperature changes.

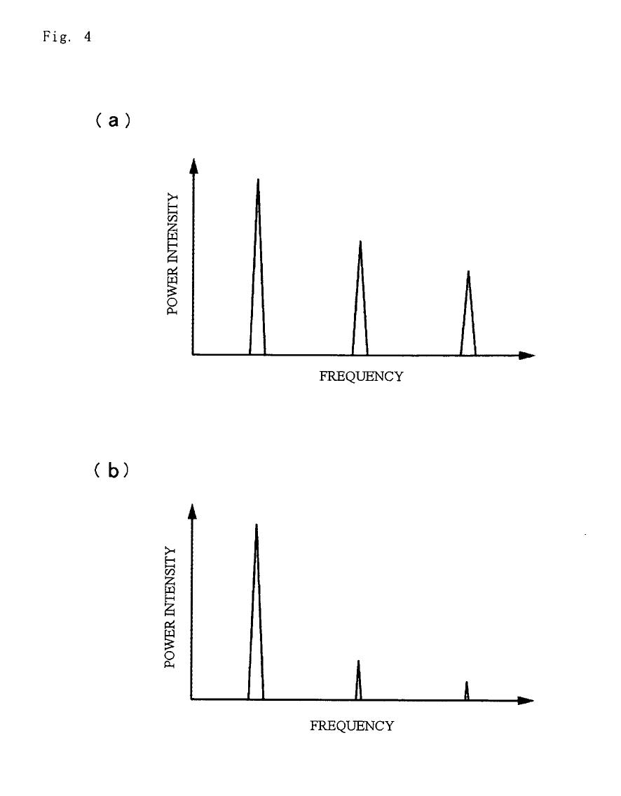

FIG. 4(a) and FIG. 4(b) show conceptual charts of a frequency response when the purity of the sine wave in the oscillation output is low and when the purity thereof is high, respectively. When the purity of the sine wave of the oscillation output is high, noise is smaller than when the purity is low.

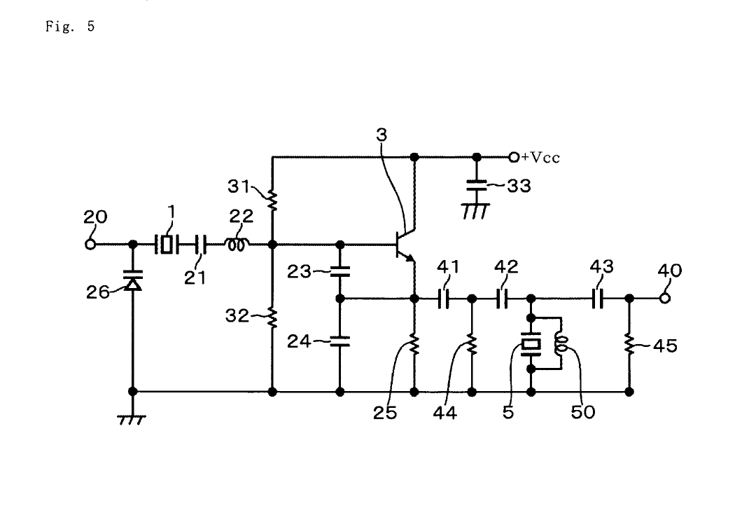

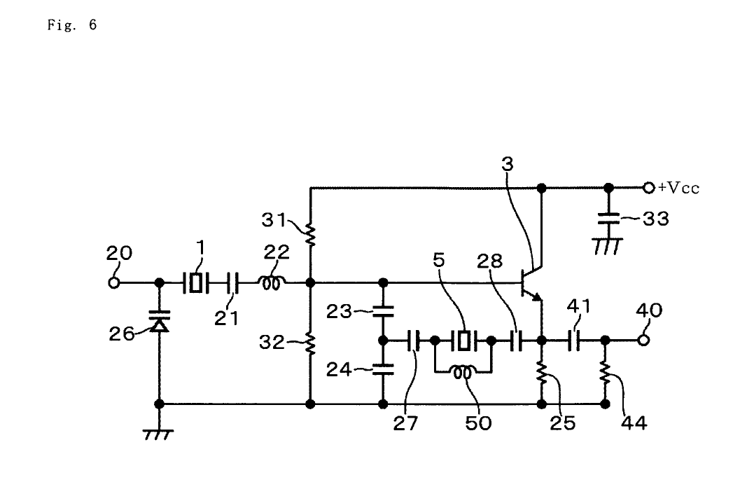

Here, other examples of the present invention are shown in FIG. 5 and FIG. 6. In the example in FIG. 1, the quartz-crystal resonator 5 for waveform shaping is connected in series when seen from the output terminal 40 side, but in an example in FIG. 5, it is connected in parallel. In this case as well, the same effects as those of the structure in FIG. 1 can be obtained.

Further, in the examples in FIG. 1 and FIG. 5, the quartz-crystal resonator 5 for waveform shaping is provided outside the oscillation loop, but in an example in FIG. 6, it is provided inside the oscillation loop. Specifically, the quartz-crystal resonator 5 for waveform shaping is connected between the midpoint of the capacitors 23, 24 for voltage division and the emitter of the transistor 3. Further, capacitors 27, 28 for impedance adjustment are provided at both ends of the quartz-crystal resonator 5. The capacitors 27, 28 for impedance adjustment function for capacitance adjustment in order to obtain the resonance inside the oscillation loop. In this case as well, the waveform of the frequency signal output from the transistor 3 is shaped by the quartz-crystal resonator 5, which produces the same effects.

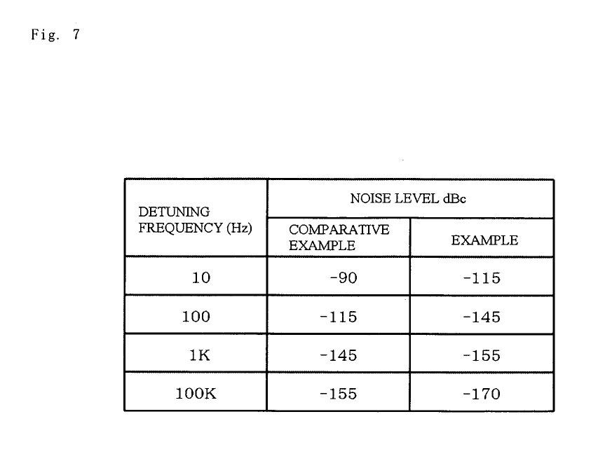

Next, by using the quartz-crystal oscillator of the embodiment shown in FIG. 1, noise level was studied for each detuning frequency regarding an output of a buffer amplifier, which is connected to an output side of the capacitor 43. Consequently, the results shown in FIG. 7 were obtained. A set frequency of the quartz-crystal resonator 1 for oscillation of this example is 30.175 MHz. Further, as a comparative example, the same test was conducted without using the quartz-crystal resonator 5 for waveform shaping in the aforesaid example, and its results are also shown in FIG. 7. As is seen from these results, the use of the quartz-crystal resonator 5 for waveform shaping contributes to a reduction in phase noise. Furthermore, an output voltage was 13 mV in the example, but was 10 mV in the comparative example.

### Second Embodiment

In a second embodiment of the present invention, an oscillator is formed by using a SAW (Surface Acoustic Wave) resonator being an elastic wave resonator for oscillation instead of the quartz-crystal resonator 1 for oscillation in the first embodiment and using a SAW resonator for waveform shaping instead of the quartz-crystal resonator 5 for waveform shaping in the first embodiment. The SAW resonator for oscillation and the SAW resonator for waveform shaping use a common piezoelectric piece, and are formed so that the SAW resonator for oscillation and the SAW resonator for waveform shaping exhibit the same frequency-temperature characteristic which represents a temperature-dependent frequency change.

In the example using the SAW resonators instead of the quartz-crystal resonators as well, the distortion of an output waveform is reduced, which makes it possible to obtain a sine wave with high purity. Further, since the SAW resonator for oscillation and the SAW resonator for waveform shaping use the common piezoelectric piece, it can be said that the SAW resonators both exist in the same temperature environment. Since the SAW resonators both exhibit the same frequency-temperature characteristic, their resonance points change in the same manner even if the temperature under which the SAW resonators are placed changes. Therefore, even if the temperature changes, the effect of reducing the phase noise is not impaired.

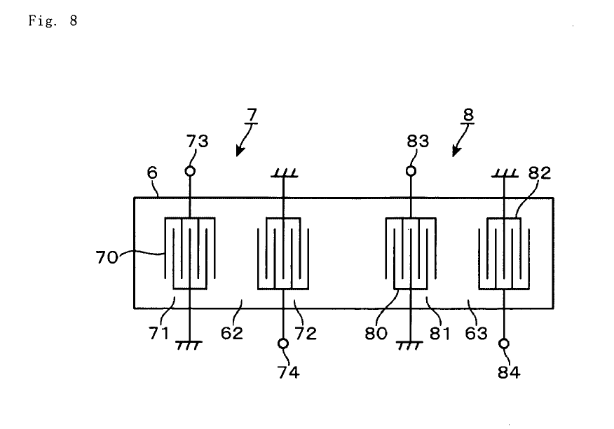

FIG. 8 is a block diagram showing a SAW resonator 7 for oscillation and a SAW resonator 8 for waveform shaping which use a common piezoelectric piece. 6 denotes the common piezoelectric piece, and on a left portion and a right portion of the piezoelectric piece 6, device areas 62, 63 are formed. On the device area 62, the SAW resonator 7 for oscillation is provided. In the SAW resonator 7, a transmission electrode 71 and a reception electrode 72 each formed by an IDT (Interdigital transducer) electrode 70 are arranged side by side in a propagation direction of SAW on a surface of the piezoelectric piece 6. Out of frequency signals input from an input port 73, a signal with a resonant frequency decided by the structure of the IDT electrodes 70 is output with a large power intensity from an output port 74.

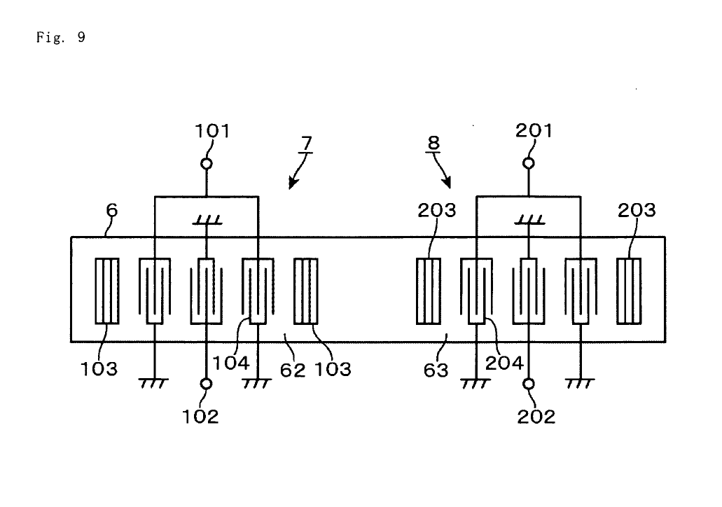

On the other device area 63, the SAW resonator 8 for waveform shaping with the same structure is also provided. 80 denotes an IDT electrode, 81 denotes a transmission electrode, 82 denotes a reception electrode, 83 denotes an input port, and 84 denotes an output port. The SAW resonators may also be longitudinally coupled resonators shown in FIG. 9. In FIG. 9, portions with the same reference numerals as those in FIG. 8 represent to equivalent portions. 101, 201 denote input ports, 102, 202 denote output ports, 103, 203 denote grating reflectors, and 104, 204 denote IDT electrodes.

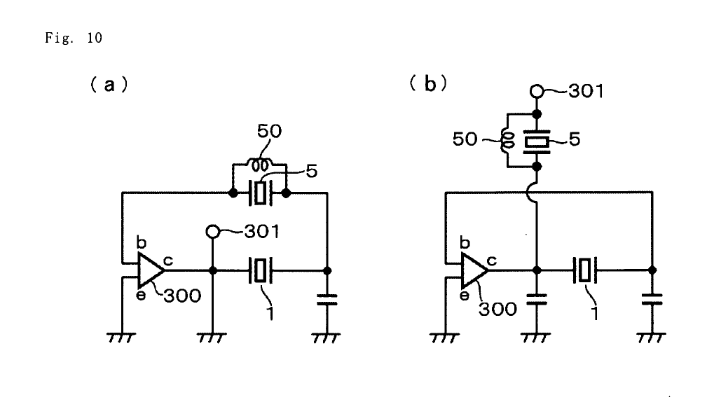

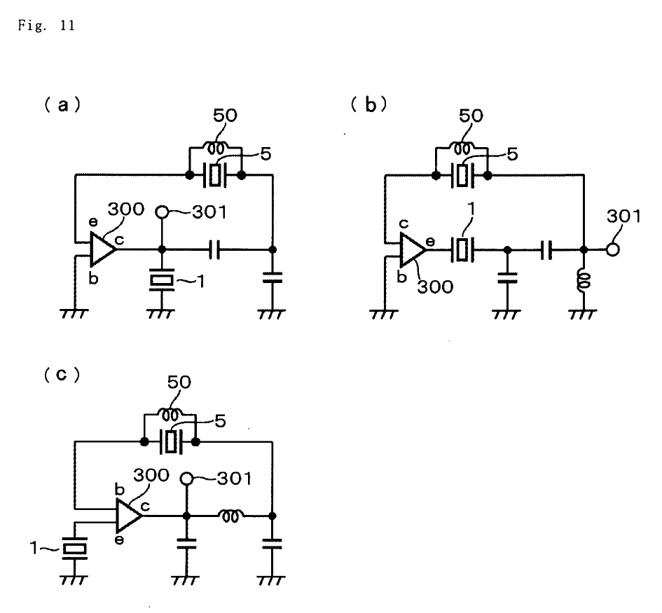

The oscillator circuit used in the present invention is not limited to the Colpitts circuit shown in FIG. 1 and may be any of circuits shown in FIGS. 10(a), 10(b) and FIGS. 11(a) to 11(c). FIG. 10(a) shows an example where the quartz-crystal resonator 5 for waveform shaping is provided in an oscillation loop of a Pierce oscillator circuit, and FIG. 10(b) shows an example where the quartz-crystal resonator 5 for waveform shaping is provided outside the oscillation loop of the same oscillator circuit. Further, FIG. 11(a) to FIG. 11(c) show a Clapp oscillator circuit, a Butler oscillator circuit, and a modification example of the Butler oscillator circuit respectively, and inside the oscillation loop of each of the circuits, the quartz-crystal resonator 5 for waveform shaping is provided. In each of the drawings, 300 denotes a transistor, and b, c, e denote a base, a collector, and an emitter respectively. 301 denotes an output port.

What is claimed is:

1. An oscillator which includes an oscillating part including a quartz-crystal resonator for oscillation; and an amplifying part amplifying a frequency signal oscillated by the oscillating part to feed the frequency signal back to the oscillating part, the oscillator comprising:
a quartz-crystal resonator for waveform shaping provided inside or outside an oscillation loop including the oscillating part and the amplifying part to shape the frequency signal to a sine wave, and
an inductor connected in parallel to the quartz-crystal resonator for waveform shaping and causing parallel resonance at an intended output frequency with a parallel capacitance exhibited in an equivalent circuit of the quartz-crystal resonator for waveform shaping,
wherein the quartz-crystal resonator for oscillation and the quartz-crystal resonator for waveform shaping use a common quartz-crystal piece, with a pair of electrodes forming an oscillation area of the quartz-crystal resonator for oscillation being provided on both surfaces of the quartz-crystal piece respectively, and with a pair of electrodes forming an oscillation area of the quartz-crystal resonator for waveform shaping being provided on the both surfaces of the quartz-crystal piece respectively, and
wherein the electrodes of the quartz-crystal resonator for oscillation and the electrodes of the quartz-crystal resonator for waveform shaping are not elastically coupled to each other or have weak elastic coupling.

2. The oscillator according to claim 1, wherein an electrode area of the quartz-crystal resonator for waveform shaping is larger than an electrode area of the quartz-crystal resonator for oscillation.

3. An oscillator which includes: an oscillating part including an elastic wave resonator for oscillation; and an amplifying part amplifying a frequency signal oscillated by the oscillating part to amplify the frequency signal back to the oscillating part, the oscillator comprising
an elastic wave resonator for waveform shaping provided inside or outside an oscillation loop including the oscillating part and the amplifying part to shape the frequency signal to a sine wave,
wherein IDT electrodes of the elastic wave resonator for oscillation and the elastic wave resonator for waveform shaping are disposed on a common piezoelectric piece.
